(19) United States
(12) Patent Application Publication
(10) Pub. No.: US 2025/0258195 A1
(43) Pub. Date: Aug. 14, 2025

(54) TEST PIN WITH POGO PIN AND SURROUNDING COIL SPRING FOR TESTING DEVICES UNDER TEST

(71) Applicant: Infineon Technologies AG, Neubiberg (DE)

(72) Inventors: Soon Lai KHO, Melaka (MY); Nee Wan KHOO, Melaka (MY)

(73) Assignee: Infineon Technologies AG, Neubiberg (DE)

(21) Appl. No.: 19/049,730

(22) Filed: Feb. 10, 2025

(30) Foreign Application Priority Data
Feb. 14, 2024 (DE) 10 2024 104 059.9

(51) Int. Cl. G01R 1/067; G01R 1/073

(52) U.S. Cl. CPC G01R 1/06722; G01R 1/07307

(57) ABSTRACT

A test pin for a test device and a test device including a test pin is disclosed. One example comprises a test pin for a test device for electrically contacting a device under test to be tested, the test pin comprising an at least partially electrically conductive pogo pin, and an at least partially electrically conductive coil spring surrounding the pogo pin at least over a major portion of a length of the pogo pin.

### CROSS-REFERENCE TO RELATED APPLICATION

This Utility Patent application claims priority to German Patent Application No. 10 2024 104 059.9 filed Feb. 14, 2024, which is incorporated herein by reference.

### BACKGROUND

### Technical Field

Various embodiments relate generally to a test pin, a test device, and a method of testing a device under test.

### Description of the Related Art

After completing manufacture of semiconductor chips or packages of such semiconductor chips, such IC (integrated circuit) devices are usually tested concerning their function. For this purpose, a test device with one or more test pins is provided in which such products are tested as devices under test (DUT).

However, the technical effort required for such tests is significant because test pins may suffer from wear and need to be exchanged frequently in a cumbersome and time-consuming procedure. Moreover, the reliability and correctness of test results (i.e. the reliability that a DUT having passed the test is in fact acceptable and that a DUT having failed the test is in fact unacceptable) is still improvable. Furthermore, testing devices under test may still suffer from insufficient electrical performance.

### SUMMARY

There may be a need for a test pin enabling test of devices under test with good electrical performance.

According to an exemplary embodiment, a test pin for a test device for electrically contacting a device under test to be tested may be provided, the test pin comprising an at least partially electrically conductive pogo pin, and an at least partially electrically conductive coil spring surrounding the pogo pin at least over a major portion of a length of the pogo pin.

According to another exemplary embodiment, a test device for electrically testing a device under test may be provided, the test device comprising a base body, and at least one test pin having the above mentioned features assembled with the base body and configured for electrically contacting a device under test for conducting a test signal from and/or to the device under test.

According to yet another exemplary embodiment, a method of testing a device under test may be provided, the method comprising contacting a test pin having the above mentioned features with an electrically conductive structure of the device under test, applying a test signal via the test pin to the electrically conductive structure of the device under test as a stimulus, and detecting a response of the device under test to the test signal.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a three-dimensional view of constituents of a test pin according to an exemplary embodiment.

FIG. 2 shows a test device with a test pin, such as the one of FIG. 1, according to an exemplary embodiment.

FIG. 3 shows different views of the test pin according to FIG. 1.

FIG. 4 shows a side view of different constituents of the test pin according to FIG. 1.

FIG. 5 shows a three-dimensional view of a plurality of test pins according to FIG. 1 together with a device under test.

FIG. 6 shows the structure of FIG. 5 without surrounding coil spring.

FIG. 7 shows a side view and a cross-sectional view of the test pin according to FIG. 1, however without further coil spring.

FIG. 8 shows different views of the test pin according to FIG. 1 with information indicating a mechanical stress acting on the test pin during operation.

FIG. 9 shows details of constituents of the test pin according to FIG. 1.

FIG. 10 shows different views of the test pin according to FIG. 1.

FIG. 11 shows a three-dimensional view of part of a test pin according to an exemplary embodiment.

FIG. 12 shows a cross-sectional view of a test pin according to FIG. 11.

FIG. 13 shows different views of a feature providing a self-cleaning function of a test pin according to an exemplary embodiment.

FIG. 14 shows a side view of the test pin according to FIG. 13.

FIG. 15 shows a cross-sectional view of a pogo pin of a test pin according to an exemplary embodiment.

FIG. 16 shows a schematic exploded view of a test pin with coaxial configuration for providing an electromagnetic interference protection function according to an exemplary embodiment.

FIG. 17 shows a schematic three-dimensional view of the test pin according to FIG. 16.

FIG. 18 shows a test device with a test pin according to FIG. 16.

FIG. 19 shows a cross-sectional view of a test pin according to FIG. 16.

FIG. 20 shows the cross-sectional view of FIG. 19 together with an electric connection circuitry of the test pin.

### DETAILED DESCRIPTION

There may be a need for a test pin enabling test of devices under test with good electrical performance.

According to an exemplary embodiment, a test pin for a test device for electrically contacting a device under test to be tested may be provided, the test pin comprising an at least partially electrically conductive pogo pin, and an at least partially electrically conductive coil spring surrounding the pogo pin at least over a major portion of a length of the pogo pin.

According to another exemplary embodiment, a test device for electrically testing a device under test may be provided, the test device comprising a base body, and at least one test pin having the above mentioned features assembled with the base body and configured for electrically contacting a device under test for conducting a test signal from and/or to the device under test.

According to yet another exemplary embodiment, a method of testing a device under test may be provided, the method comprising contacting a test pin having the above mentioned features with an electrically conductive structure of the device under test, applying a test signal via the test pin to the electrically conductive structure of the device under test as a stimulus, and detecting a response of the device under test to the test signal.

According to an exemplary embodiment, a test device and a test pin may be provided wherein the latter may have a test tip which may be connected to electrically contact and test a device under test (DUT). Advantageously, the test pin comprises a (for instance metallic) pogo pin as a core, and a (for example metallic) coil spring arranged circumferentially around the pogo pin or at least a major portion thereof. Exemplary embodiments may fulfil at least one of the following two purposes: On the one hand, the coil spring arranged around the pogo pin may provide an extended electric path to distribute a higher electric current for the test pin. Consequently, the test pin may endure a higher testing current. In view of the skin effect, such a test pin may be highly appropriate in particular for high frequency applications because the combined provision of pogo pin and coil spring may increase the skin area along which current propagates even at high frequencies. Additionally or alternatively, arranging at least one coil spring around a pogo pin in a test pin may advantageously mitigate external electromagnetic interference (EMI) to the inner pogo pin. As a result, such embodiments may benefit from a strong suppression of disturbing interfering electromagnetic radiation from an environment.

Advantageously, a pogo pin being nested together with one or more outer coil springs, which may be wrapped around the central pogo pin, may form multiple radially parallel electric connections, optionally together with a bundle of brush like flexible conductors, to achieve a plurality of advantageous effects: Firstly, a higher current and a higher contact area may be obtained for achieving a better current carrying capability. Moreover, a larger skin area may be obtained for efficiently addressing the skin effect, in particular when testing at higher frequency. Apart from this, it may be possible to reduce a self-inductance of the test pin by providing multiple parallel connections. Optionally, contact tip cleaning efficiency may be promoted by configuring the test pin to execute a rotational and/or radial scrub movement during operation. The latter optional feature may efficiency reduce contamination of the test pin.

### DESCRIPTION OF FURTHER EXEMPLARY EMBODIMENTS

In the following, further exemplary embodiments of the test pin, the test device, and the method will be explained.

In the context of the present application, the term “device under test” (DUT) may particularly denote an electronic component, such as a semiconductor package, which shall be tested concerning its desired functionality after manufacture. In particular, the device under test may be an electronic member configured as a power semiconductor, in particular for automotive applications. Such devices under test may require an electric test involving the application of high voltage and/or high current electric test signals (for instance applying a current of up to 100 Ampère or more).

In the context of the present application, the term “test pin” may particularly denote an at least partially electrically conductive elongate structure configured for carrying an electric signal transported from the test pin towards a device under test, and/or vice versa.

In the context of the present application, the term “test device” may particularly denote an apparatus configured for testing a device under test by applying a stimulus signal to one or more test pins and from there to the device under test, and capturing and analyzing an electric response signal from the device under test for example using the same and/or other test pins.

In the context of the present application, the term “pogo pin” may particularly denote a, for example spring-loaded, pin being an electrical connector for testing electronic devices and/or applications. Pogo pins may be used in view of their pronounced durability, and the resilience of their electrical connection to avoid mechanical shock and vibration.

In the context of the present application, the term “coil spring” may particularly denote an at least partially electrically conductive structure with a resilient element (such as a winding, for instance a helical winding). A coil spring may provide a resilient or an elastic property and may thereby provide a spring function. For example, the coil spring may be a helically wound filament or wire, or a sleeve with a helical recess.

In the context of the present application, the term “coil spring surrounding the pogo pin at least over a major portion of a length of the pogo pin” may particularly denote that an axial extension of part of or the entire coil spring overlapping with an axial extension of part of or the entire pogo pin is more than half of the length of the pogo pin, in particular at least 75% of the length of the pogo pin, preferably at least 90% of the length of the pogo pin, and most preferably the entire length of the pogo pin.

In the context of the present application, the term “base body” may particularly denote a support or carrier of the test pin or of multiple test pins.

In the context of the present application, the term “test signal” may particularly denote an electric signal which may be applied by a test device to a test pin and from there to a device under test and/or propagating from the device under test to the same or another test pin and from there to the test device.

In embodiments, a function of the pogo pin is to provide this preferably harder inner pin as part of the test pin. Such a pogo pin may have an interior and/or an exterior spring, wherein a spring of a pogo pin may be denoted as pogo pin spring. The presence of a pogo pin may provide both elasticity and rigidity and/or other characteristics, such as stability and a guiding function, between the inner pogo pin and the external coil spring(s). While pogo pins may have a spring, different embodiments of a pogo pin may have for example an inner spring or an outer spring. In embodiments, the pogo pin may have a solid barrel (such as a cylinder body in a middle portion of the pogo pin) that allows a softer outer helical (for instance flat) coil spring to be guided coaxially. Without a stiffer inner core provided by the pogo pin, the outer helical flat coil may behave flimsy. Thus, the pogo pin may provide stability and guidance to the at least one exterior coil spring. The center core may be partially free of a spring effect, for example if the length of the center core is shorter than the length of the outer coil spring (for example helical coil). However, the interior space of the pogo pin may be used particularly efficiently when an inner spring is present.

In an embodiment, the construction of the pogo pin can be as follows: The pogo pin may comprise an at least partially electrically conductive pogo pin spring, wherein the pogo pin may further comprise a piston movably coupled with the pogo pin spring and may further comprise a stationary barrel in which at least part of the pogo pin spring and the piston are guided. While the construction of a pogo pin may vary in different embodiments, a pogo pin may comprise a plunger or piston, a barrel, a spring, and optionally a biasing mechanism for biasing the spring into a default configuration.

In an embodiment, a coil spring surrounding the pogo pin over a major portion of a length of the pogo pin should surround the pogo pin so that the surrounded major length section of the pogo pin is larger than an optionally not surrounded minor length section of the pogo pin. For example, the major portion of the pogo pin may be at least 75%, in particular at least 90%, of the entire length of the pogo pin.

Preferably, the length of the coil spring may be as long as the internal pogo pin, or may be ±20% or even ±10% of the length of the internal pogo pin. In particular, it may also be possible that the coil spring is a little bit shorter than the pogo pin. During operation, the pogo pin may be pressed down first, then both the pogo pin and the coil spring may touch the device under test (DUT) during electrical testing. Preferably, the pogo pin and the coil spring may simultaneously touch the DUT when the electrical current is applied. Another option may be that the coil spring is even further shorter than explained before, but it electrically contacts the shoulder or upper part of the pogo pin. In this configuration, the current may first go through the upper part of the pogo pin, then be distributed to the middle and lower part of the pogo pin and the external coil spring. More generally, the length of the outer flat helical coil spring versus the center pogo pin may depend on design requirements.

In an embodiment, the coil spring comprises an electrically conductive bent sheet, for example having a recess. In embodiments, a flat coil spring may be used which comprises an electrically conductive and preferably circumferentially closed sheet. However, alternatively, said coil spring may have windings in the shape of circular elements in a cross-sectional view. Furthermore, a gist of an exemplary embodiment may be to provide an additional inner rigid pogo pin in combination with an external coil spring which can be a softer or relaxed coil spring, or a hard coil. A helical flat coil spring (which may be made, for example, of flat ribbon stainless steel) may be a preferred option, whereas a round helical coil spring may be possible as well.

In an embodiment, the coil spring surrounds the pogo pin over the entire length of the pogo pin. Hence, the entire axial extension of the pogo pin may be circumferentially surrounded by the one or more coil springs. This may protect the pogo pin over its entire length. Furthermore, this may allow for a current flow along both the pogo pin and the at least one coil spring along comparably long flow paths.

In an embodiment, the coil spring comprises a sleeve with a helical recess. Thus, the structure of the coil spring may be helical. Hence, the coil spring may be manufactured based on a flat sheet which may be bent to form a cylindrical sleeve. Said sleeve may be provided with a helically extending recess, thereby providing the sleeve with a spring function. The coil spring may have a spiral configuration. In particular a flat sheet-based coil spring may combine a resilient characteristic with guidance and stability for providing an overall robust test pin. However, alternatively, the at least one coil spring may be provided as a helically wound filament or wire.

In an embodiment, the sleeve has the helical recess only in a front portion, whereas a back portion of the sleeve is free of a recess. Hence, the back portion of the sleeve may be free of a spring function, whereas the spring function may be provided by the front portion of the sleeve only. This may increase the stability of the test pin as a whole. More specifically, there may be a further benefit of only part of the coil spring having a recess, so that only the recess will allow the spring mechanism to take place: Having one end of the coil spring with no recess may reduce the springy movement of the coil spring at the respective end. This may help to reduce or even eliminate undesired digging of the test pin into a connected component (in particular printed circuit board (PCB) pad digging) as rotational and/or radial movement of the test pin may intensify impact on said component (for instance a PCB pad worn out and digging). Besides, if for example the helical coil spring at the PCB end or the like is designed to be soldered to PCB via holes, it also makes sense to fix the movement of the helical coil at the PCB end.

In an embodiment, the test pin comprises at least one further at least partially electrically conductive coil spring surrounding the coil spring. By providing a plurality of coil springs, one of which being wrapped around the other, and preferably being coaxially arranged around the pogo pin, the current carrying capability of the test pin as a whole may be further increased. Furthermore, when a plurality of coil springs are arranged around a pogo pin, it is for example possible that one of said coil springs is used for increasing the current carrying capability of the test pin whereas another one of said coil springs may be used for providing electromagnetic interference protection. It is however also possible that a plurality of nested coil springs are used for enhancing current carrying capability of the test pin.

In an embodiment, the at least one further coil spring comprises a sleeve with a helical recess. To put it shortly, the construction of the further coil spring can be for example as described above for the first coil spring. Hence, embodiments with a sleeve having a helical recess or a helically wound filament or wire may be for instance possible. However, it is for example possible that the winding pitch is larger for the exterior coil spring than for the interior coil spring.

In an embodiment, the helical recesses of the coil spring and of the at least one further coil spring are mutually displaced in an axial direction. Such a mutually displaced configuration (see for example reference signs 118 and 126 in FIG. 4) in which recesses defining windings of the coil spring and of the further coil spring are offset from each other may provide the benefit that the two coil springs are not easy sticking together when both are pressed. To put it shortly, it may be for instance possible that recesses of sheet-type coil spring and further coil spring are axially misaligned on purpose to prevent that coil spring and further coil spring get stuck.

In an embodiment, the pogo pin and the coil spring are connected electrically in parallel. This may allow to guide current through the pogo pin and through the one or more coil springs individually and independently. For instance, the pogo pin, the coil spring and/or the at least one further coil spring can be electrically isolated from each other, so that each of them may carry electric current during operation. Therefore, it may be for example possible that the inner surface of the coil spring and/or of the at least one further coil spring is or are non-conductive, so that for example the inner surface of the coil spring will not electrically connect to the inner pogo pin, and/or the inner surface of the at least one further coil spring will not electrically connect to the coil spring. In an embodiment, the coil spring and the at least one further coil spring may however not need to be insulated, for example when maintaining an air gap in between. This may be advantageous to reduce the mechanical friction between them during operation of the test pin (which may involve for instance a plunging movement).

In an embodiment, the pogo pin and the coil spring are coaxial. To put it shortly, a coaxial pogo pin configuration may be provided. Such a coaxial arrangement may provide an EMI (electromagnetic interference) shielding arrangement. Thus, electric signals or current propagating along the pogo pin may be prevented from being influenced by electromagnetic stray radiation from an environment thanks to a surrounding coil spring, which may for example be brought to an electric reference potential, such as ground.

In an embodiment, the test pin comprises an electrically insulating gap radially between the pogo pin and the coil spring. For instance, a physical distance or a non-conductive distance or interposer element may be provided between pogo pin and coil spring. In particular, an air gap or an additional material layer may be provided between pogo pin and coil spring. An air gap may be a preferred embodiment, because the friction between pogo pin and coil spring may then be reduced.

In an embodiment, the test pin comprises an electrically insulating barrier element, for example an electrically insulating barrier coil spring, radially between the pogo pin and the coil spring. For example, the electrically insulating barrier element may be arranged on an exterior surface of the pogo pin. Such an insulating barrier element may ensure a reliable electrical decoupling between the pogo pin and the coil spring. This may be desired to achieve an independent current carrying function of pogo pin and coil spring or for keeping pogo pin and coil spring at different electrical potentials (for instance when the coil spring provides an EMI protection function for the pogo pin).

In an embodiment, the electrically insulating barrier element radially separates the pogo pin being configured as sense contact from the coil spring being configured as force contact. This may relate to a preferred embodiment in which the pogo pin is set as sense contact and the one or more outer coil springs is or are set as force contact. In another embodiment, the pogo pin can be additionally set for force contact. In yet another embodiment, the function of the pogo pin (then as force contact) and the coil spring (then as sense contact) may be exchanged. In the following, the terms “sense contact” and “force contact” will be explained: In order for current-voltage curves of the device under test (DUT) to be accurately measured, the instrumentation of the test device including test pin may ensure small parasitic resistance values in the interconnection between the DUT terminals and the test device with test pin(s). For this purpose, a four terminal connection configuration (also called Kelvin configuration) may be provided in the test device including test pin(s). In such a Kelvin configuration, the sense leads or contacts may measure the electric potential. This may be done at a point as close as possible to the DUT, so as to achieve small or negligible voltage drop due to contact parasitic resistance in the probes and due to cable parasitic resistance. The force contact may denote a signal line, whereas the sense contact may denote a feedback line. If the sense contact is connected to the force contact at a point close to the DUT (sensing point), the system may work to settle the output voltage at a sensing point in setting voltage through analog feedback.

In an embodiment, the length of the pogo pin is substantially equal (for example with a deviation within ±10%) to a length of the coil spring. Preferably, the coil spring may surround the pogo pin essentially along the entire length of both pogo pin and coil spring.

In an embodiment, a free end portion of the coil spring and/or of at least one further coil spring (which may for example surround the aforementioned coil spring) comprises a brush structure configured for at least partially removing contaminants from the test pin during operation. For example, the brush structure may comprise a circumferential array of brush elements at the free end portion. Preferably, the brush elements may extend parallel to each other along an axial direction. By configuring the free end portion of the coil spring as a brush structure, a self-cleaning or contamination suppressing effect of the test pin may be achieved. This may extend the lifetime of a test pin.

The above description has focused predominantly on an application of the test pin according to which the external coil spring may work for distributing or re-distributing the electric current so that the test pin can carry more current, for example a factor of three when two coil springs are provided. In another embodiment, another or a further function of using the most external coil spring as EMI shielding may be provided. In such an embodiment, the shielding coil spring does not electrical connect leads of the device under test (for instance when the shielding coil spring is not exposed at a pin tip of the test pin where facing a device under test), but may be connected to a reference potential (for example to a grounding trace of a test device), where the whole test pin is part of or connects to the test device.

Thus, in an embodiment, the coil spring may be electrically decoupled from the pogo pin, and may be preferably electrically coupled or configured to be electrically coupled with a reference potential, so as to provide the pogo pin with an electromagnetic interference protection by the coil spring. Preferably, the pogo pin and the coil spring are coaxial in this embodiment. Descriptively speaking, the pogo pin and the coil spring may form a coaxial pogo pin. By electrically insulating the outer helical coil spring from the inner core pogo pin (for instance if this outer helical coil spring is not used to boost the current capability, skin effect, etc.), it may be possible to use, implement or configure the outer coil spring as EMI shield to protect the inner pogo pin from EMI. A configuration making this possible may configure pogo pin and surrounding coil spring as a coaxial structure, which may for instance be denoted as coaxial pogo pin. In such an embodiment, the shielding layer or helical layer may be wrapped around the pogo pin. Therefore, it may be possible to reduce the total size of the pogo pin. Further, there may be a grounding function of the shielding or helical layer which may be achieved for example by a ground trace of a printed circuit board (PCB) which may be part of a testing equipment. Furthermore, the pogo pin may also be part of the testing equipment. In such an embodiment of the pogo pin, there may be no electrical interconnect between the shielding or helical layer (which may form the outer coil spring) and the inner pogo pin, so that they can be electrically insulated from each other and brought to different electric potentials. Further, such embodiments may also disable an interface (such as a contact) between the shielding or helical layer (in particular an exterior coil spring) and the leads of the semiconductor package to be tested. During testing, it is possible in an embodiment that the shielding layer (such as an exterior coil spring) may not touch the lead, so as to achieve a shielding of an interference with electromagnetic stray radiation.

In an embodiment, the test device comprises a plurality of test pins having the above mentioned features assembled with the base body. When using an array of test pins, a throughput of a test may be increased and a test sequence may be executed in parallel. In particular, the method may comprise testing the device under test by contacting simultaneously a plurality of test pins having the above mentioned features with the electrically conductive structure of the device under test.

In an embodiment, the method comprises applying the test signal with an electric current of at least 500 A. At such high electric current values, a partial transport of said current by the pogo pin and a partial transport of said current by the at least one surrounding coil spring may be of utmost advantage.

In an embodiment, the method comprises applying the test signal with a pulse length of not more than 10 μs. Short current pulses may lead to high current peaks, which may render the transmission of such a high current partially by a pogo pin and partially by at least one surrounding coil spring advantageous.

In an embodiment, the method comprises testing a power semiconductor device as the device under test. Power semiconductor device tests may involve high electric power applied through test pins. Thus, using test pins according to exemplary embodiments for testing power semiconductor devices may be highly appropriate in view of the current carrying capability not only of the pogo pin but also of at least one coil spring. For example, a tested semiconductor component (such as a semiconductor chip) may be used for power applications (for instance in the automotive field) and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

In an embodiment, the method comprises testing the device under test by contacting both the pogo pin and the coil spring with the electrically conductive structure of the device under test. This may make it possible to transmit test current both by the pogo pin and by the at least one coil spring to a DUT.

In an embodiment, the method comprises testing the device under test by contacting only the pogo pin but not the coil spring with the electrically conductive structure of the device under test. The coil spring may then be brought to an electric reference potential, for instance ground potential, to provide an EMI protection to the test pin.

In an embodiment, the test device comprises a control unit configured for applying one or more electric test signals via one or more test pins to the device under test as one or more electric stimulus signals and detecting one or more electric response signals from the device under test in response to the one or more test signals via one or more test pins. Such a control unit may control overall operation of the test device. In particular, such a control unit (for instance a processor) may generate and apply one or more electric test signals to one or more base structures. Such an electric test signal may propagate to the pin tip of the test pin and can then be applied to a corresponding electrically conductive structure of the DUT. After having applied the one or more test signals to the DUT, they will be processed by the DUT in accordance with the electronic functionality of the DUT. As a result of this signal processing, one or more response signals are generated in response to the applied test signal(s). These one or more response signals can be transmitted electrically from the electrically conductive structure(s) of the DUT via test pin(s) to the control unit. Based on the response signal, the control unit can determine as to whether the presently analyzed DUT has passed or failed the test.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Current carrying capability of a contact pin is becoming the bottleneck in today's test environments, particularly for power devices such as semiconductor chips in silicon carbide or gallium nitride technology, for instance configured as insulated gate bipolar transistor (IGBT) chips. Modern power devices, in particular wide bandgap (WBG) devices, may require demanding high test current values for both direct current (DC) and alternating current (AC) tests. For example, AC tests, such as short circuit tests, may demand a very high peak current value from 500 A to 6500 A over a time interval of 2 μs. However, tests using test pins can also be carried out at medium current. Overcurrent can shorten a life span of test pins and may cause burn of test pins prematurely. Thus, a solution would be desired in contact pin technology which can drive ultra-high current without the risk of excessive damage.

On package level, the contacting area on the lead may have a limited space. The use of copper clips instead of bond wires may have significant advantages in current capability at device level. However, even when the device is capable to operate at high current, a bottleneck is the test capability to test high current with low inductance, in particular for WBG devices. The ability to breakthrough test capability would be desired for WBG technology.

In summary, conventional shortcomings of testing devices with test pins are burn of a pin tip due to overcurrent, pronounced self-inductance of a contact pin, and excessive pin tip contamination over time. Also stray inductance of test system may be an issue. Moreover, limitations in terms of the skin effect may cause high resistance and signal loss at high frequency testing. As known by those skilled in the art, a current flow occurs predominantly in the skin of the conductor rather than over the entire cross-section of the conductor at high frequency testing. In view of this phenomenon called skin effect, when there is insufficient skin area to allow a sufficiently high current at high frequency, impedance of the contact may increase, which may cause signal losses.

Conventional approaches to overcome limitations in terms of pin current carrying capability are to place or populate as much pins as possible on a very limited lead area. By achieving an optimum contact force and selecting a high conductivity of pin tip material (for instance by manufacturing test pins using BeCu, silver, gold plating), current carrying capability of test pins may be increased. For certain devices, it may be possible to place numerous pogo pins on the same lead. However, this may have the disadvantage that there may remain a limitation to place more pins beyond a lead area.

According to an exemplary embodiment, a test pin may be provided which may be to be coupled to a test device for electrically testing a DUT, such as a semiconductor chip or package. The test pin may be constructed with an interior electrically conductive pogo pin surrounded by one or more electrically conductive coil springs. By taking this measure, one or both of the following functionalities may be integrated in the test pin: Firstly, both the pogo pin and at least one coil spring arranged around a perimeter of the pogo pin may conduct electric current during testing. As a result, a higher testing current and thus a higher current carrying capability of the test pin may be achieved. In another embodiment, surrounding a pogo pin by at least one coil spring may function as a coaxial pogo pin and may thereby strongly suppress external electromagnetic radiation from deteriorating the functionality of the test pin. To put it shortly, the coil spring of this embodiment may provide an electromagnetic interference (EMI) protection. Thus, the test pin can be used in particular advantageously for high frequency applications without the risk of pronounced EMI-based distortions.

To put it shortly, a nested contact pin may be provided by exemplary embodiments. More specifically, a pogo pin may be nested together with one, two or more than two outer coil springs (which may be for instance flat coil springs). This may allow the contact force and contact area to increase (for example to double or triple) while conserving the unused space, thus improving current carrying capability of contact pins. Providing nested pins may also provide a larger skin area to mitigate the skin effect when carrying out a test at high frequency, for instance an AC dynamic test. Connecting more contact pins in parallel may help to reduce self-inductance which may be critical for high speed high frequency tests. Advantageously but not necessarily, an outer helical flat spring may induce a rotational and outwardly operating scrub mechanism which may lead to a self-cleaning effect allowing to reduce or even to get rid of contaminations.

In a preferred embodiment, a pogo pin may be nested together with one or more outer (for instance flat bent) coil springs forming multiple parallel and radial connections. A further option is to combine this configuration with a bundle of brush-like flexible conductors.

Advantageously, test pins of exemplary embodiments may allow to achieve a high force and high contact area for obtaining an excellent current carrying capability. Moreover, an obtainable enlarged skin area may allow to mitigate the skin effect when carrying out a test at a high frequency. Moreover, it may be possible to reduce the self-inductance of the test pin by providing multiple parallel electric connections, for instance one through the pogo pin and at least one through at least one exterior coil spring. Optionally, an improved cleaning efficiency of the contact tip may be achieved by providing a rotational and radial scrub movement.

The nesting principle of a test pin according to an exemplary embodiment may place the pogo pin inside of at least one coil spring, thereby making it possible that the pogo pin passes through a cavity or hollow of the at least one coil spring, thus eliminating empty space in the test pin. By providing a higher number of springs involved in a test pin, it may be possible to produce a higher contact force. Furthermore, this may make it possible to provide a larger contact area which may avoid peaks of current density, which may allow, in turn, to efficiently suppress the risk of pin burn at a pin tip of a test pin. A larger contact skin may improve contact impedance during high frequency testing. This may allow to reduce or even minimize current and/or signal losses due to the skin effect. By providing more pin elements connected in parallel, it may be possible to dilute the self-inductance of the contact pins. As an advantageous optional feature, it may be possible to configure an outer helical flat coil spring to induce a rotational and outwardly operating scrub mechanism which can self-clean the contamination on pin tips of the test pin. Moreover, providing a nested pin design may enable the inner pogo pin to operate as a sense pin and an outer coil spring to function as force pin (or vice versa), thereby improving the lead space utilization. Furthermore, the user experience may be improved by test pins according to exemplary embodiments, since a nested contact pin may allow a user to freely add or remove a nested component depending on the present situation, needs and requirements. This may allow to use the test pin with flexibility and in a highly customizable configuration.

To put it shortly, a test pin according to an exemplary embodiment may allow to achieve a high current, a low inductance, a low resistance, and optionally a self-cleaning function of a test or contact pin. A test pin according to an exemplary embodiment may be particularly advantageous for use in semiconductor testing of power devices, and for wide bandgap technology. Furthermore, a test pin according to an exemplary embodiment may be freely adjustable and customizable.

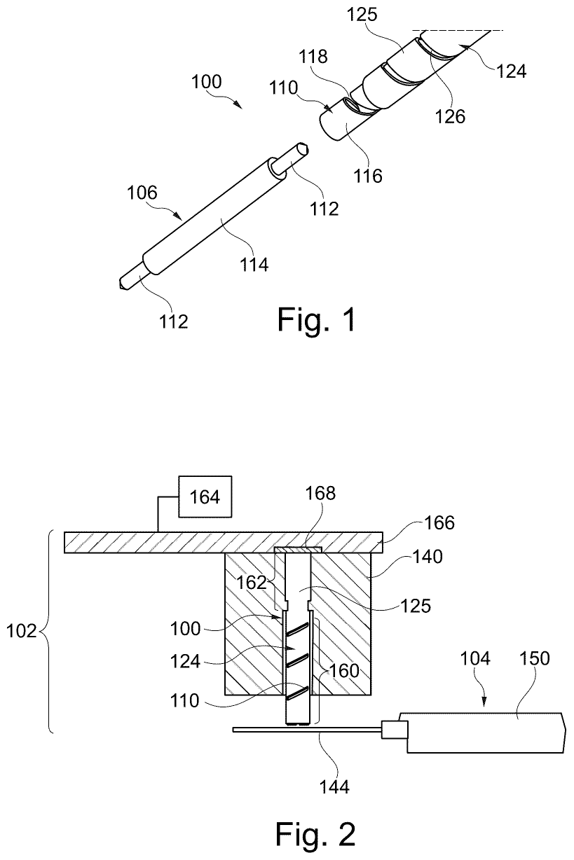

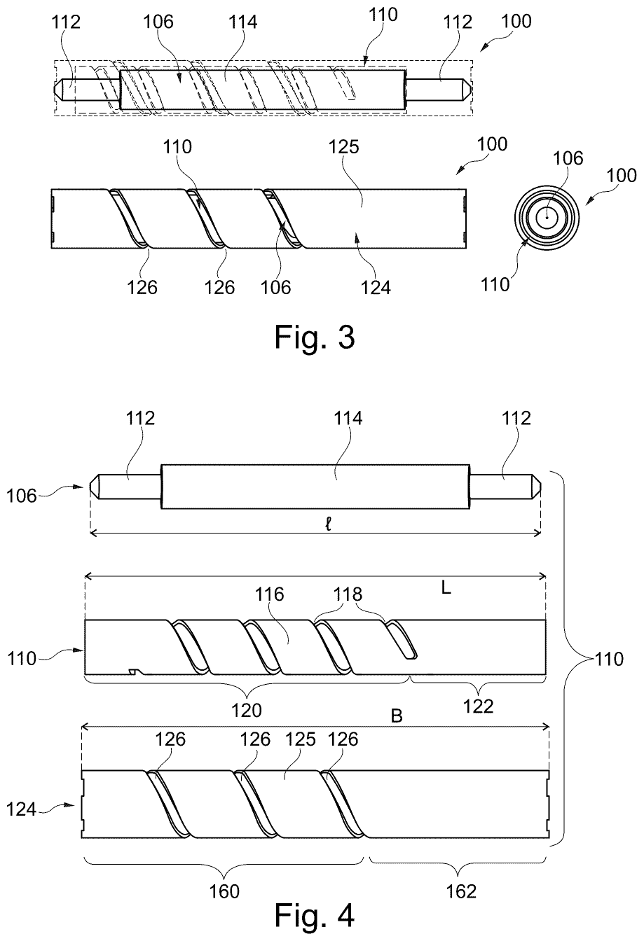

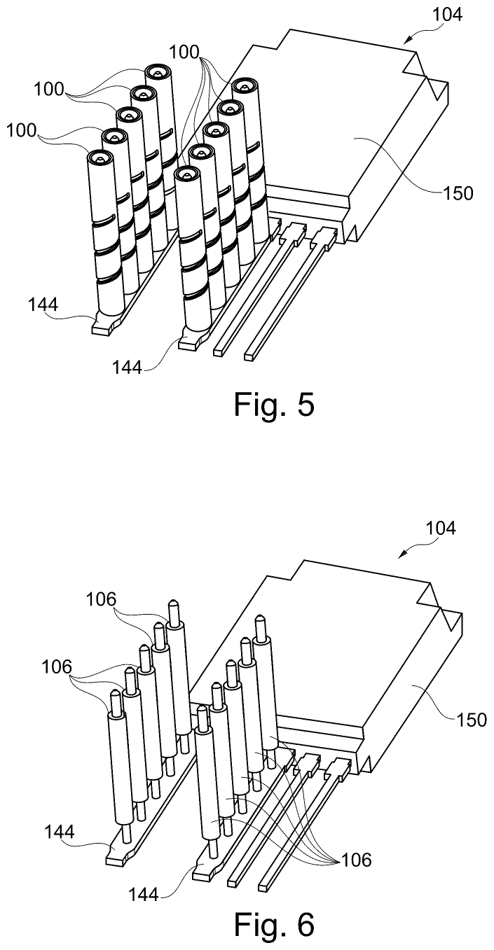

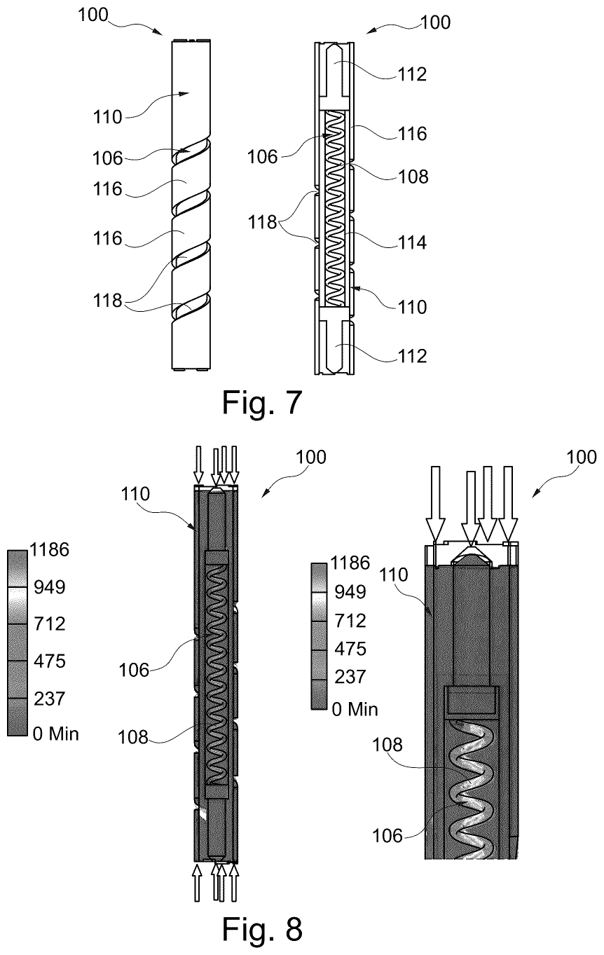

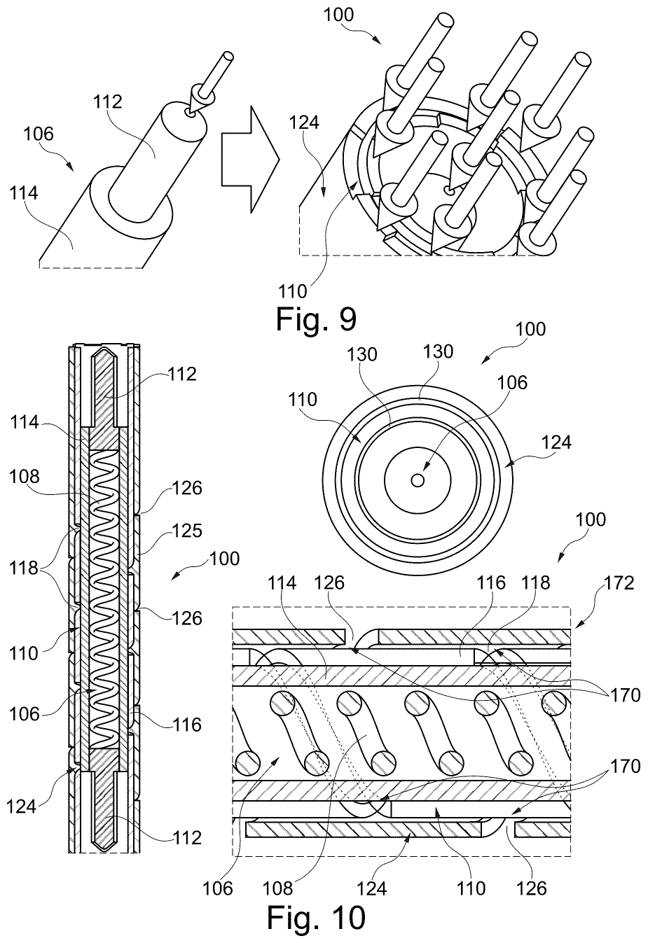

FIG. 1 shows a three-dimensional view of constituents of a test pin 100 according to an exemplary embodiment. FIG. 2 shows a test device 102 with a test pin 100, such as the one of FIG. 1, according to an exemplary embodiment. FIG. 3 shows different views, i.e. a transparent side view, a plan view, and a real side view, of the test pin 100 according to FIG. 1. FIG. 4 shows a side view of different constituents of the test pin 100 according to FIG. 1. FIG. 5 shows a three-dimensional view of a plurality of test pins 100 according to FIG. 1 together with a device under test 104. FIG. 6 shows the structure of FIG. 5 without surrounding coil springs 110, 124. FIG. 7 shows a side view and a cross-sectional view of the test pin 100 according to FIG. 1 without further coil spring 124. FIG. 8 shows different views of the test pin 100 according to FIG. 1 with information indicating a mechanical stress distribution acting on the test pin 100 during operation. FIG. 9 shows details of constituents of the test pin 100 according to FIG. 1. FIG. 10 shows different views of the test pin 100 according to FIG. 1.

More specifically, the test pins 100 shown in FIG. 1 to FIG. 10 are provided for use with or in a test device 102 (see FIG. 2) and are configured for electrically contacting a device under test (DUT) 104 to be tested. In the shown embodiment, the device under test 104 may be a package with a semiconductor power chip (not shown) encapsulated in an encapsulant 150 (such as a mold compound). Pads or terminals of the semiconductor power chip may be coupled to an exterior of the encapsulant 150 by electrically conductive leads of said package. Said electrically conductive leads are an example for electrically conductive structures 144 of the device under test 104 to which an electric stimulus signal may be applied and/or at which an electric response signal may be detected. Thus, the electrically conductive structures 144 may be brought in contact with a tip of one or more tests pins 100 for carrying out an electric functional test.

Now referring for instance to FIG. 1, the test pin 100 comprises an electrically conductive pogo pin 106 which may form a core of the test pin 100. Furthermore, the test pin 100 may comprise an electrically conductive coil spring 110 surrounding the pogo pin 106 laterally at least over a major portion of a length 1 of the pogo pin 106. As best seen in FIG. 4, the length 1 of the pogo pin 106 may be the same as a length L of the coil spring 110 so that the pogo pin 106 may be surrounded along its entire length 1 by the coil spring 110. Thus, the coil spring 110 surrounds the pogo pin 106 over the entire length 1 of the pogo pin 106. Furthermore, the test pin 100 may comprise a further electrically conductive coil spring 124 surrounding the coil spring 110. For example, a length B of the further coil spring 110 may be the same as the length L of the coil spring 110 and the length 1 of the pogo pin 106. Other dimensions are however possible.

Now referring still to FIGS. 1 and 10, but also to FIG. 15, the pogo pin 106 may comprise an at least partially electrically conductive pogo pin spring 108 (for instance a helical spring made of a spirally wound wire or filament). Moreover, the pogo pin 106 may further comprise a piston 112 (or even two opposing pistons 112 on both opposing ends, see FIG. 1 and FIG. 10) movably coupled with the pogo pin spring 108. Beyond this, the pogo pin 106 comprises a stationary barrel 114 in which the pogo pin spring 108 and a respective end of the one or two pistons 112 may be guided.

Now referring to the construction of the coil spring 110, the latter may be formed based on a metallic tubular or cylindrical sheet which may be bent so as to be circumferentially closed. A helical recess 118 may be formed in at least a portion of said sheet to equip the latter with a spring function. Thus, the coil spring 110 may be formed as a metallic sleeve 116 with a helical recess 118. As can be seen best in FIG. 4, the sleeve 116 may have the helical recess 118 only in a front portion 120 (which may face a device under test 104 during operation), whereas a back portion 122 (which may be connected to other constituents of a test device 102 during operation) of the sleeve 116 is free of a recess. As a result, the back portion 122 may provide the coil spring 110 with high stability, whereas the front portion 120 may contribute to resilient or springy characteristics.

Also the further coil spring 124 comprises a tubular or cylindrical metallic sleeve 125 with a helical recess 126 to provide the further coil spring 124 with a spring function. As can be seen best in FIG. 4, the sleeve 125 can have the helical recess 126 only in a front portion 160, whereas a back portion 162 of the sleeve 125 can be free of a recess. As a result, the back portion 162 may provide the further coil spring 124 with high stability, whereas the front portion 160 may contribute to resilient or springy characteristics.

As shown in FIG. 4, the helical recesses 118, 126 of the coil spring 110 and of the further coil spring 124 may be mutually displaced in an axial direction. In said mutually displaced configuration, the recesses 118, 126 defining windings of the coil spring 110 and of the further coil spring 124, respectively, are offset from each other along an axial direction. This may provide the benefit that the two coil springs 110, 124 are not easy sticking together when both are pressed.

In the shown test pin 100, pogo pin 106 may form a central core surrounded by coil spring 110 being surrounded, in turn, by further coil spring 124. Although not shown in FIG. 1 to FIG. 10, one or more additional coil springs may be provided radially surrounding the further coil spring 124. On the other hand, further coil spring 124 may also be omitted to obtain a very compact test pin 100, see FIG. 7.

As shown, the pogo pin 106, the coil spring 110 and the further coil spring 124 are nested. Furthermore, they are connected electrically in parallel. A test current may propagate through each of the pogo pin 106, the coil spring 110 and the further coil spring 124, so that test pin 100 may have a very high current carrying capability. In the illustrated embodiment, the pogo pin 106, the coil spring 110 and the further coil spring 124 are arranged coaxial.

Moreover, a plurality of tests pins 100 can be grouped in rows or in two-dimensional array, see FIG. 5 and FIG. 6. For example, five test pins 100 per lead may be foreseen.

Advantageously, a test pin 100 according to an exemplary embodiment may be constructed based on a pogo pin 106 which is nested with a second outer flat helical coil spring 110 and followed by a third outer helical coil spring 124. This may allow to increase the contact pin density in a limited lead area, for example by up to three times or more. As the number of contacts of a test pin 100 may be increased, also the current carrying capability of the test pin 100 which may be increased, for example by a factor of three. To put it shortly, test current may flow in parallel through metallic pogo pin 106, metallic coil spring 110 and metallic further coil spring 124.

With the illustrated configuration of test pin 100, self-inductance of the contact or test pin 100 may be reduced significantly compared with conventional approaches. In the following, the possible reduction of the self-inductance of contact or test pin 100 constructed of pogo pin 106, coil spring 110 and further coil spring 124 will be explained: Assuming that L1 denotes the pogo pin (106) inductance, L2 denotes the coil spring (110) inductance and L3 denotes the further coil spring (124) inductance, the resulting inductance L is calculated as L=(1/L1+1/L2+1/L3)⁻¹. Hence, the self-inductance of test pin 100 may be reduced by connecting pogo pin 106, coil spring 110 and further coil spring 124 in parallel. To put it shortly, the stray inductance may be reduced by the additional provision of coil spring 110 (and preferably further coil spring 124), as compared to a conventional approach in which only pogo pin 106 is present.

Furthermore, the configuration of test pin 100 may increase the skin area to mitigate the impact of the skin-effect, which may be particularly advantageous for high frequency tests.

As best seen in FIG. 9, the described configuration of test pin 100 may allow to achieve a higher contact force and contact area. For example, three times or more contact force and/or contact area may be obtained. Furthermore, three times or more of skin area may be achieved. This may improve the electric performance of test pin 100. Thus, FIG. 9 shows that the contact area of test pin 100 with regard to device under test 104 may be significantly increased by additionally providing coil spring 110 (and preferably also further coil spring 124) as compared to a configuration which comprises only pogo pin 106. According to exemplary embodiments, this may lead to a very low contact resistance.

Now referring to FIG. 10, an electrically insulating gap 130 may be set, formed or maintained radially between the central pogo pin 106 and the inner coil spring 110 and/or may be set, formed or maintained radially between the inner coil spring 110 and the outer or further coil spring 124. This allows to operate the pogo pin 106, the coil spring 110 and the further coil spring 124 electrically independently from each other.

For example, coil spring 100 may be constructed with a 2.2 mm winding pitch, an inner diameter of 1.40 mm, an outer diameter of 1.70 mm, and a flat coil thickness of 0.15 mm. For instance, the further coil spring 124 may be embodied with a 2.8 mm winding pitch, an inner diameter of 1.80 mm, an outer diameter of 2.10 mm, and a flat coil thickness of 0.15 mm. Preferably, the coil spring 110 and the further coil spring 124 do not overlap each other. Electrically insulating gap 130 (for instance an air gap) may allow to provide a smooth spring movement with little friction. Appropriate materials for making coil springs 110, 124 are beryllium copper alloy, steel, steel alloy, nickel, nickel alloy, bronze, bronze alloy. A more extended list of suitable metallic conductive materials that can be used to make the helical coil springs 110, 124 are steel Inox, nickel-beryllium, cuivre-beryllium, copper-nickel, copper titane, steel carbon, brass, bronze, maillechort, copper-silicon, Inconel 600, copper-iron, and copper-cadmium.

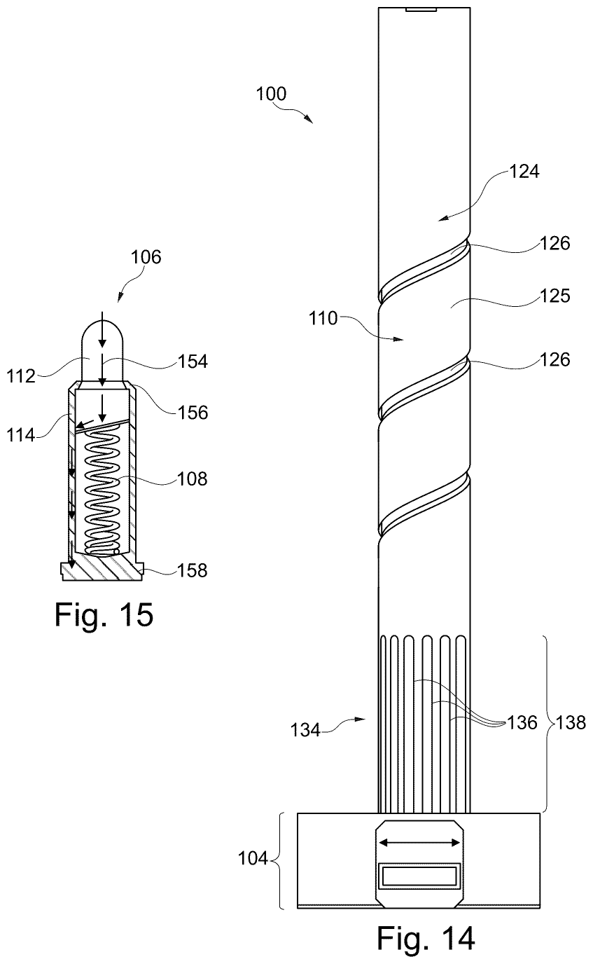

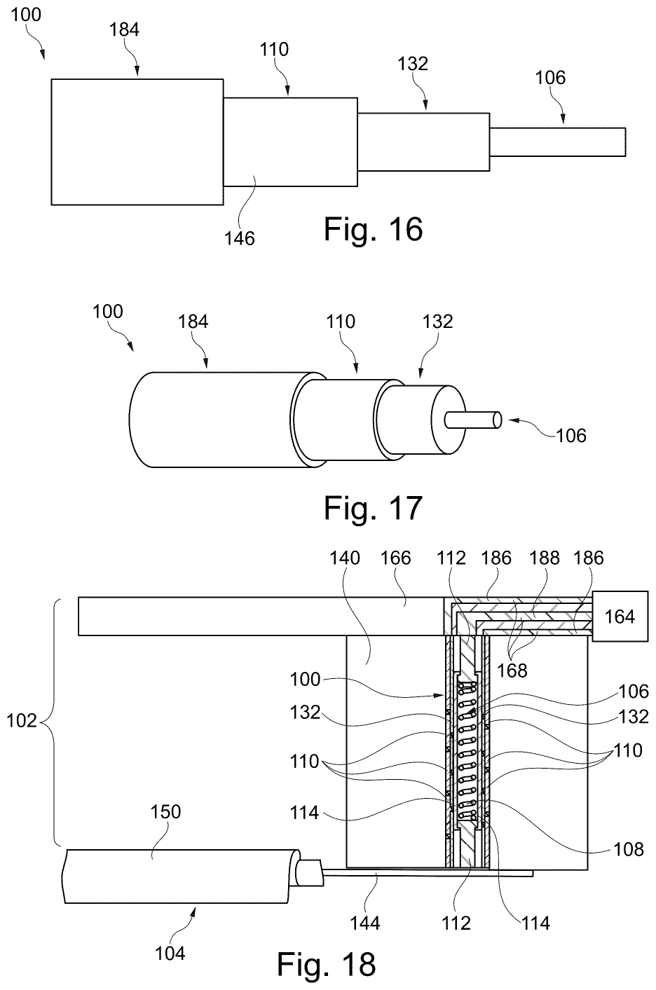

In summary, the embodiment of FIG. 1 to FIG. 10 allows to obtain a high current capability, a low inductance, a low impedance, a large skin area, and optionally an auto self-cleaning contact pin (see the below described embodiment of FIG. 13 and FIG. 14). This may be highly advantageous in semiconductor testing, particularly in power device testing, and in wide bandgap device testing. When configuring coil spring 110 (in the absence of coil spring 124) or the coil spring 124 surrounding coil spring 110 as described below referring to FIG. 16 to FIG. 20, it may be possible to additionally obtain an EMI protection, in particular for pogo pin 106.

Referring specifically to FIG. 8, van Mises stress in MPa is shown during operation of test pin 100. As shown, only a very moderate van Mises stress is exerted to test pin 100 compared with conventional approaches.

As shown in a detail 172 of FIG. 10, a plurality of openings 170 in sleeves 116, 125 for forming helical recesses 118, 126 may allow to obtain soft and/or resilient properties in dedicated sections of coil springs 110, 124.

FIG. 2 shows a test device 102 with the described test pin 100 according to an exemplary embodiment.

More specifically, FIG. 2 schematically shows a test device 102 for testing devices under test 104 (DUTs) by carrying out an electronic full function test according to an exemplary embodiment. The devices under test 104 may be IC (integrated circuit) devices, for instance semiconductor packages for high power applications.

The test device 102 comprises a housing or a base body 140 which may comprise an electrically insulating material. One or a plurality of electrically conductive test pins 100 may be assembled with and may extend through the base body 140. The test pins 100 are configured for electrically contacting electrically conductive structures 144, such as leads (or pads or traces), of the device under test 104 for conducting, during the test, electric test signals from the test device 102 to the device under test 104, and from the device under test 104 back to the test device 102.

A control unit 164, which may be a microprocessor or the like, can be coupled to a mounting structure 166 (such as a printed circuit board, PCB) and may be configured for applying the test signals via mounting structure 166 and via the test pins 100 to the device under test 104 as a stimulus. The mounting structure 166 may be electrically coupled with the test pin 100 by one or more electric contacts 168. The control unit 164 may be further configured for detecting a response from the device under test 104 in response to the application of the test signals via the test pins 100. Based on the functionality of a device under test 104, a certain pattern of the response signals is expected when a certain device under test 104 works properly. Thus, an analysis of the response signals can be used as a basis for a decision as to whether the device under test 104 has passed the test and can therefore be considered as a good product which can be shipped to a customer, or whether the device under test 104 has failed the test. If the latter decision is taken, a further test can be carried out, the device under test 104 may be further processed, or may be thrown away.

For example, the execution of the test may comprise applying the test signal with an electric current of at least 500 A and/or with a pulse length of not more than 10 μs. Test pins 100 according to exemplary embodiments and described above may be capable of withstanding such harsh conditions which may occur, for instance, when testing a power semiconductor device as the device under test 104.

During testing the device under test 104, it may be possible to contact both the pogo pin 106 and the coil spring 110 with the electrically conductive structure 144 of the device under test 104. Optionally, also at least one further coil spring 124 (when present) may be contacted with the electrically conductive structure 144 of the device under test 104. By distributing the test current over a plurality of metallic elements (see reference signs 106, 110, 124) high current may be applied without the risk of damage.

In another embodiment, testing the device under test 104 may be accomplished by contacting only the pogo pin 106 but not the coil spring 110 (or the pogo pin 106 and the coil spring 107, but not the further coil spring 124) with the electrically conductive structure 144 of the device under test 104. This may allow to provide an electromagnetic interference (EMI) protection by the outermost coil spring 110 (or 124), in particular when the latter is brought to an electric reference potential, such as ground (see FIG. 18 to FIG. 20).

During execution of a test application, the test pin 100 may be fixed at the mounting structure 166 and may be actuated to contact the device under test 104.

As shown in FIG. 2, the sleeve 125 of the further coil spring 124 has the helical recess 126 only in front portion 160, whereas back portion 162 of the sleeve 125 is free of a recess. By omitting helical recess 126 in back portion 162, the spring characteristics of the further coil spring 124 may be focused to the front portion 160 only, whereas the back portion 162 is rigid and thus highly appropriate for fixing with socket housing to avoid PCB digging. A corresponding design may be used for coil spring 110 (see reference signs 120, 122 and the above description referring to FIG. 4).

By providing helical recesses 126/118 only in front portions 160/120 facing the device under test 104, the spring characteristics is provided at the lower part of the nested pogo pin 106, rendering the test pin 100 highly appropriate for actuation at the side of the device under test 104. The opposing upper end may be fixed by a socket housing, thereby obtaining significantly less spring movement at the mounting side of the test pin 100. On the other hand, the device end of the test pin 100 is more dynamic during actuation.

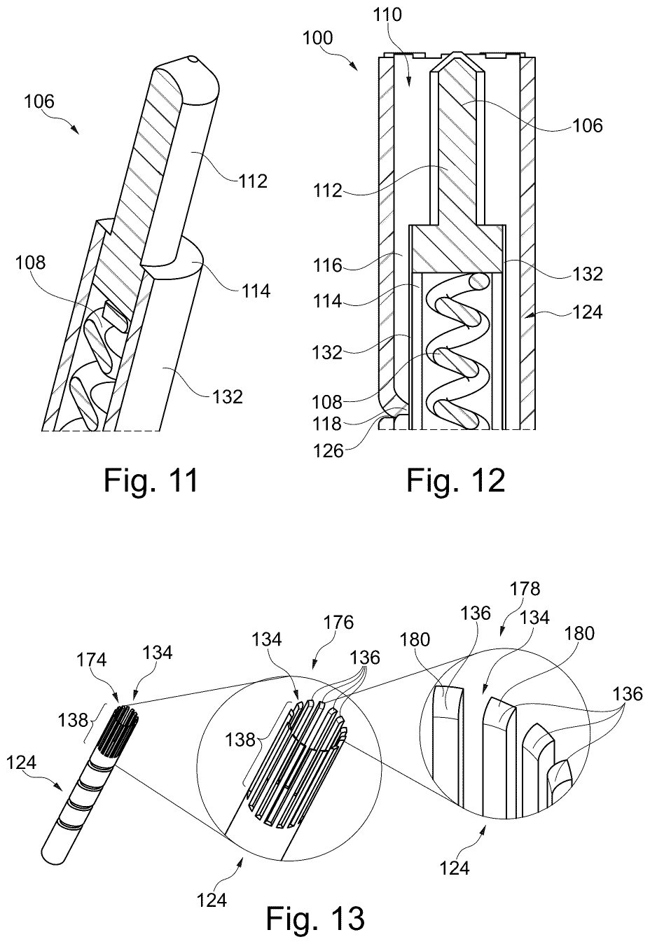

FIG. 11 shows a three-dimensional view of part of a test pin 100 according to an exemplary embodiment. FIG. 12 shows a cross-sectional view of the test pin 100 according to FIG. 11.

Referring to FIG. 11 and FIG. 12, an electrically insulating barrier element 132 radially separates the pogo pin 106, being configured as sense contact, from the coil springs 110, 124, being configured as force contact.

In the shown embodiment, the electrically insulating barrier element 132 is formed as a dielectric coating on the barrel 114 of the pogo pin 106. Alternatively, a separate electrically insulating barrier element 132 may be interposed between pogo pin 106 and coil spring 110. In yet another embodiment, an electrically separating air gap may be formed between the pogo pin 106 and the coil spring 110.

As already mentioned, pogo pin 106 may function as sense pin which may measure an electric potential or other electric signal. The coil spring 110 may function as first force pin, whereas the optional further coil spring 124 may function as second force pin. A respective force pin may denote a signal line capable of applying an electric signal to the respective coil spring 110, 124. Thus, the inner spring may be used for signal sensing and the outer spring(s) may be used for signal forcing. By making the inner pogo pin 106 electrically insulating at its exterior surface thanks to electrically insulating barrier element 132, a force-sense configuration may be obtained within the same test pin 100.

FIG. 13 shows different views of a feature providing a self-cleaning function of a test pin 100 according to an exemplary embodiment. FIG. 14 shows a side view of the test pin 100 according to FIG. 13.

Referring to FIG. 13, an overview 174, a first detail 176 and a further enlarged second detail 178 of a head portion of a test pin 100 of an exemplary embodiment are shown for illustrating features which provide a self-cleaning function. More specifically, a free end portion 138 of the coil spring 110, i.e. an end of the coil spring 110 facing the device under test 104 during a test operation, comprises a brush structure 134 which is configured for at least partially removing contaminants from the test pin 100 during operation. Said brush structure 134 comprises a circumferential array of brush elements 136 (for example at least five or at least ten) at the free end portion 138. During operation of the test pin 100 for testing a device under test 104, the circumferentially distributed plurality of brush elements 136 may form a plurality of contacting parts which may rotate and spread radially outwardly during operation. This may scrap at the pin tip for removing contamination. This effect may be further enhanced by a wedge-type geometry of the brush elements 136 at the free end, see reference sign 180. Thus, the outer flat coil spring 124 and/or coil spring 110 (or only coil spring 110 in the absence of further coil spring 124) may offer a rotational and outward scrub movement which may lead to self-cleaning.

By configuring pin tips or pin ends at the helical flat coil spring(s) 110/124 with multiple branches of brush-like pin sections (preferably with radius tip), the contact area with a device under test 104 may be increased. Along with rotational and radial outward scrubbing, this may allow to clean off contamination. With multiple branches of a brush pin tip together with the provision of one or more helical coil flat springs 110/124, a self-cleaning mechanism may be provided by a rotational and outward scrub mechanism. Advantageously, only very moderate van Mises stress may be exerted to the brush elements 136 during operation of test pin 100.

FIG. 15 shows a cross-sectional view of a pogo pin 106 of a test pin 100 according to an exemplary embodiment.

In addition to the elements of the pogo pin 106 described above referring to FIG. 1 to FIG. 10, the pogo pin 106 of FIG. 15 shows a router of current 154, and a crimping 156 keeping the piston 112 in the barrel 114. In the pogo pin configuration of FIG. 15, a solder tail 158 is also foreseen. For instance, a height of the pogo pin 106 of FIG. 15 may be in a range from 5 mm to 9 mm, preferably in a range from 6 mm to 7.5 mm.

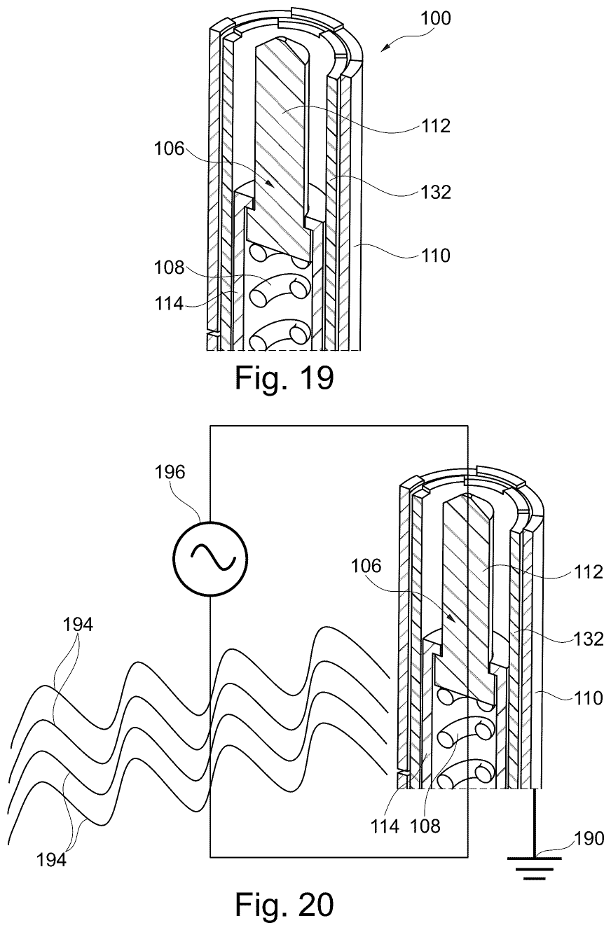

FIG. 16 shows a schematic exploded view of a test pin 100 with coaxial configuration for providing an electromagnetic interference protection function according to an exemplary embodiment. FIG. 17 shows a schematic three-dimensional view of the test pin 100 according to FIG. 16. FIG. 18 shows a test device 102 with the test pin 100 of the type according to FIG. 16. FIG. 19 shows a detailed cross-sectional view of the test pin 100 according to FIG. 16. FIG. 20 shows the cross-sectional view of FIG. 19 together with an electric connection circuitry of the test pin 100. Descriptively speaking, the embodiments of FIG. 16 to FIG. 20 provide a structure of an external helical coil spring 110/124 for providing an electromagnetic interference (EMI) shielding function for the inner pogo pin 106 (and optionally to the inner helical coil spring 110 in the presence of an outer coil spring 124).

First referring to FIG. 16 and FIG. 17, a schematic exploded view (FIG. 16) and a three-dimensional schematic view (FIG. 17) of a test pin 100 are shown in which pogo pin 106 is provided as an interior metallic (for example copper) conductor. The pogo pin 106 may be surrounded by an electrically insulating barrier element 132 which is here embodied as a tubular dielectric insulator. The electrically insulating barrier element 132 is surrounded, in turn, by coil spring 110 (or more generally the most external coil spring, for instance in the presence of multiple coil springs 110, 124 the outermost coil spring 124). For example, the coil spring 110 comprises an electrically conductive braid 146, or a continuous sleeve. A protective coating 184, for instance a protective plastic layer, may surround the outermost coil spring 110 as a protective and electrically insulating exterior jacket. The most external coil spring 110 may provide an EMI shielding function for the pogo pin 106, especially when it connects to a ground or another fixed reference potential.

Thus, the test pin 100 according to FIG. 16 and FIG. 17 may comprise electrically insulating barrier element 132, for example an electrically insulating barrier coil spring, radially between the pogo pin 106 and the coil spring 110. For example, the electrically insulating barrier element 132 may be arranged on an exterior surface of the pogo pin 106.

Advantageously, the coil spring 110 may be electrically decoupled from the pogo pin 106 and may be electrically coupled with a reference potential (such as ground potential) for providing the pogo pin 106 with an electromagnetic interference protection.

FIG. 18 shows a configuration of a test device 102 with a test pin 100 having an EMI protection feature. FIG. 19 shows a cross-section through the test pin 100 of FIG. 18, and FIG. 20 illustrates a circuitry for connecting the outermost coil spring 110 to an electric reference potential 190 and for connecting pogo pin 106 with a test signal source 196 for providing an electric test signal.

Descriptively speaking, the embodiment of FIG. 18 to FIG. 20 may configure test pin 100 as a coaxial pogo pin, for example by maintaining a 50 (2 characteristic impedance. In other words, pogo pin 106 may be converted into an EMI shield protected pogo pin 106 thanks to corresponding configuration in particular of the outermost coil spring 110.

For this purpose, the electric contacts 168 of mounting structure 166 of test device 102 may be provided with one or more electric reference potential traces 186 (such as ground traces) and one or more signal traces 188.

In the described configuration, the inner pogo pin 106 may be maintained as electrically conductive path to carry an electric test signal. Furthermore, the pogo pin 106 may be surrounded by interposed electrically insulating material in form of electrically insulating barrier element 132. The latter may act as high permittivity medium. Electrically insulating barrier 132 may be followed, at its exterior surface, by outer conductive coil spring 110 coupled to electric reference potential 190 (for example a grounding).

Descriptively speaking, the described configuration may turn pogo pin 106 into a coaxial configuration with exterior coil spring 110 to provide an EMI shielding of the pogo pin 106 by the coil spring 110. Consequently, electromagnetic radiation 194 from an environment will be shielded by exterior coil spring 110 being coupled to electric reference potential 190. Thus, electric test signals provided by test signal source 196 to pogo pin 106 will be prevented, thanks to EMI protection features 110, 132, 190, from being influenced excessively by the electromagnetic radiation 194.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A test pin for a test device for electrically contacting a device under test to be tested, the test pin comprising:
an at least partially electrically conductive pogo pin; and
an at least partially electrically conductive coil spring surrounding the pogo pin at least over a major portion of a length of the pogo pin.

2. The test pin according to claim 1, wherein the coil spring comprises an electrically conductive bent sheet, for example having a recess.

3. The test pin according to claim 1, wherein the coil spring surrounds the pogo pin over the entire length of the pogo pin.

4. The test pin according to claim 1, wherein the coil spring comprises a sleeve with a helical recess.

5. The test pin according to claim 4, wherein the sleeve has the helical recess only in a front portion, whereas a back portion of the sleeve is free of a recess.

6. The test pin according to claim 1, comprising at least one further at least partially electrically conductive coil spring surrounding the coil spring.

7. The test pin according to claim 6, wherein the at least one further coil spring comprises a sleeve with a helical recess.

8. The test pin according to claim 4, wherein the helical recesses of the coil spring and of the at least one further coil spring are mutually displaced in an axial direction.

9. The test pin according to claim 1, comprising at least one of the following features:
wherein the pogo pin and the coil spring are connected electrically in parallel;
wherein the pogo pin and the coil spring are coaxial;
comprising an electrically insulating gap radially between the pogo pin and the coil spring.

10. The test pin according to claim 1, comprising an electrically insulating barrier element comprising an electrically insulating barrier coil spring, radially between the pogo pin and the coil spring.

11. The test pin according to claim 10, wherein the electrically insulating barrier element is arranged on an exterior surface of the pogo pin.

12. The test pin according to claim 10, wherein the electrically insulating barrier element radially separates the pogo pin being configured as sense contact from the coil spring being configured as force contact.

13. The test pin according to claim 1, wherein the length of the pogo pin is substantially equal to a length of the coil spring.

14. The test pin according to claim 1, wherein a free end portion of the coil spring and/or of at least one further coil spring comprises a brush structure configured for at least partially removing contaminants from the test pin during operation.

15. The test pin according to claim 14, wherein the brush structure comprises a circumferential array of brush elements at the free end portion.

16. The test pin according to claim 1, wherein the coil spring is electrically decoupled from the pogo pin, and is preferably to be electrically coupled with a reference potential, so as to provide the pogo pin with an electromagnetic interference protection by the coil spring.

17. A test device for electrically testing a device under test, the test device comprising:
a base body; and
at least one test pin according to claim 1 assembled with the base body and configured for electrically contacting a device under test for conducting a test signal from and/or to the device under test.

18. The test device according to claim 17, comprising a plurality of test pins according to claim 1 assembled with the base body.

19. A method of testing a device under test, the method comprising:
contacting a test pin according to claim 1 with an electrically conductive structure of the device under test;
applying a test signal via the test pin to the electrically conductive structure of the device under test as a stimulus; and
detecting a response of the device under test to the test signal.

20. The method according to claim 19, comprising at least one of the following features:
wherein the method comprises applying the test signal with an electric current of at least 500 A;
wherein the method comprises applying the test signal with a pulse length of not more than 10 μs;
wherein the method comprises testing a power semiconductor device as the device under test;
wherein the method comprises testing the device under test by contacting simultaneously a plurality of test pins according to claim 1 with the electrically conductive structure of the device under test;
wherein the method comprises testing the device under test by contacting both the pogo pin the coil spring with the electrically conductive structure of the device under test;
wherein the method comprises testing the device under test by contacting only the pogo pin but not the coil spring with the electrically conductive structure of the device under test.
